(19) United States
(12) Patent Application Publication
(10) Pub. No.: US 2018/0188127 A1
(43) Pub. Date: Jul. 5, 2018

(54) MEMS CAPACITIVE PRESSURE SENSOR AND MANUFACTURING METHOD

(71) Applicant: Teknologian Tutkimuskeskus VTT Oy, Espoo (FI)

(72) Inventors: Vladimir ERMOLOV, Espoo (FI); Jaakko SAARILAHTI, Helsinki (FI)

(21) Appl. No.: 15/736,436

(22) PCT Filed: Jun. 14, 2016
(86) PCT No.: PCT/FI2016/050424

§ 371 Date: Dec. 14, 2017

(30) Foreign Application Priority Data
Jun. 15, 2015 (FI) 20155461

(51) Int. Cl. G01L 9/00; B81B 3/00; B81C 1/00; G01L 19/06

(52) U.S. Cl. CPC G01L 9/0047; B81B 3/0051; B81B 2201/0264; G01L 19/0618; G01L 9/0073; B81C 1/00182

(57) ABSTRACT

According to an example aspect of the present invention, there is provided a MEMS capacitive pressure sensor (1), comprising a first electrode (17), a deformable second electrode (18) being electrically insulated from the first electrode (17) by means of a chamber (4) between the first electrode (17) and the second electrode (18), and wherein at least one of the first electrode (17) and the second electrode (18) includes at least one pedestal (5) protruding into the chamber (4). According to another example aspect of the present invention, there is also provided a method for manufacturing a MEMS capacitive pressure sensor (1).

### FIELD

The present invention relates to a pressure sensor. In particular, the present invention relates to a micro-electro-mechanical (MEMS) capacitive pressure sensor. Further, the present invention relates to a method for manufacturing a MEMS capacitive pressure sensor.

### BACKGROUND

MEMS capacitive pressure sensors are known, by means of which pressure can be sensed. MEMS technology facilitates the manufacture of compact pressure sensors. A MEMS capacitive pressure sensor requires two electrodes that move relative to each other under an applied pressure. This configuration is often accomplished by having a fixed electrode formed on a substrate while a moveable electrode is provided in a deformable membrane which is exposed to pressure that is to be sensed.

For example, document US 2015/0008543 A1 discloses a MEMS capacitive pressure sensor. The MEMS capacitive pressure sensor includes a substrate. The MEMS capacitive pressure sensor also includes a first electrode layer on the substrate. The first electrode layer is electrically connected with semiconductor devices in the substrate through electrical interconnection structures. Additionally, the MEMS capacitive pressure sensor includes a second electrode layer on the substrate. A chamber is formed between the first electrode layer and the second electrode layer. The chamber electrically insulates the first electrode layer and the second electrode layer. The first electrode layer, the second electrode layer, and the chamber form a capacitive structure. When a pressure is applied on the second electrode layer, the second electrode layer is deformed. Since the distance between the first electrode and the second electrode changes, the capacitance of the capacitive structure changes. This capacitance is then measured to determine the pressure applied to the deformable second electrode layer. Because the pressure on the second electrode layer is corresponding to the capacitance of the capacitive structure, the pressure on the second electrode layer can be converted into an output signal of the capacitive structure.

The geometry of the structures of such known MEMS capacitive pressure sensors is designed according to an expected pressure range to be measured. The sensibility of the capacitive structure may have a certain limitation. Decreasing the diameter of the second electrode layer and increasing the thickness or mechanical stress of the deformable second electrode layer will deteriorate the sensibility of the pressure sensor. On the other side, high pressure may lead to overloading of the MEMS capacitive pressure sensor. Increasing the diameter of the second electrode layer and decreasing the thickness of the second electrode layer will change the maximum measurable pressure. The sensor is overloaded when the deformable second electrode layer touches the fixed first electrode on the substrate due to bending.

Since the measurable pressure range set by geometry and material properties of the MEMS sensor structure is limited, different MEMS capacitive pressure sensors are typically used in different applications such as measurement of atmospheric pressure and measurement of hydrostatic pressure.

In view of the foregoing, it would be beneficial to provide a single MEMS capacitive pressure sensor which is applicable in an increased operational range.

### SUMMARY OF THE INVENTION

The invention is defined by the features of the independent claims. Some specific embodiments are defined in the dependent claims.

According to a first aspect of the present invention, there is provided a MEMS capacitive pressure sensor comprising a first electrode, a deformable second electrode (conductive membrane) being electrically insulated from the first electrode by means of a chamber between the first electrode and the second electrode, and wherein at least one of the first electrode and the second electrode includes at least one pedestal protruding into the chamber.

Various embodiments of the first aspect may comprise at least one feature from the following bulleted list:
the sensor is configured to mechanically connect the first electrode and the second electrode at a defined applied pressure by means of the pedestal
the pedestal is made of insulating material or includes an insulating layer which is configured to electrically insulate the first electrode and the second electrode
at least one of the first electrode and the second electrode includes an insulating layer configured to electrically insulate the first electrode and the second electrode
the pedestal is formed annularly or as a ring
at least one of an inner diameter of the pedestal, an outer diameter of the pedestal, a diameter of the chamber, a height of the pedestal, a height of the chamber, and a thickness of a deformable membrane is depending on a predetermined measurable pressure range
the sensor includes two or more pedestals each having a different height
the height of the pedestals protruding into the chamber increases in a direction radially outwards
the pressure in the chamber is substantially lower than the atmospheric pressure
the second electrode comprises at least one amorphous polysilicon layer
the first electrode is fixedly attached to a substrate made of insulating material
the first electrode and the second electrode are electrically connected to a semiconductor device in the substrate
at least one of the first electrode and the second electrode comprises a silicon wafer

According to a second aspect of the present invention, there is provided a method for manufacturing a MEMS capacitive pressure sensor, the method comprising forming a first electrode, forming a deformable second electrode, which is electrically insulated from the first electrode by means of a chamber between the first electrode and the second electrode, and forming at least one pedestal protruding into the chamber from at least one of the first electrode and the second electrode.

Considerable advantages are obtained by means of certain embodiments of the present invention. Certain embodiments of the present invention provide a single MEMS capacitive pressure sensor which is applicable in an increased operational range. Pressure measurement can be, for example, performed in different applications such as measurement of atmospheric pressure and hydrostatic pressure. Two different pressure sensors for measuring atmospheric pressure and hydrostatic pressure can be e.g. replaced by a single pressure sensor, thus reducing the footprint and production costs of the component.

Certain embodiments of the present invention further provide a method for manufacturing a MEMS capacitive pressure sensor. The method is capable of being performed simply and cost effectively. The MEMS capacitive pressure sensors can be manufactured in industrial scale.

### BRIEF DESCRIPTION OF THE DRAWINGS

FIG. 1 illustrates a schematic view of a MEMS capacitive pressure sensor, wherein a deformable electrode includes a pedestal in accordance with at least some embodiments of the present invention,

FIG. 2 illustrates a schematic view of a MEMS capacitive pressure sensor, wherein a fixed electrode includes a pedestal in accordance with at least some embodiments of the present invention,

FIG. 3 illustrates a schematic view of a MEMS capacitive pressure sensor in accordance with at least some embodiments of the present invention, wherein a pedestal of a first electrode or a second electrode is mechanically in contact with the respective other electrode,

FIG. 4 illustrates a schematic cross sectional view of a MEMS capacitive pressure sensor in accordance with at least some embodiments of the present invention,

FIG. 5 illustrates a schematic view of a first manufacturing step of a MEMS capacitive pressure sensor according to an embodiment of the present invention,

FIG. 6 illustrates a schematic view of a second manufacturing step of a MEMS capacitive pressure sensor according to an embodiment of the present invention,

FIG. 7 illustrates a schematic view of a third manufacturing step of a MEMS capacitive pressure sensor according to an embodiment of the present invention,

FIG. 8 illustrates a schematic view of a fourth manufacturing step of a MEMS capacitive pressure sensor according to an embodiment of the present invention,

FIG. 9 illustrates a schematic view of a fifth manufacturing step of a MEMS capacitive pressure sensor according to an embodiment of the present invention,

FIG. 10 illustrates a schematic view of a sixth manufacturing step of a MEMS capacitive pressure sensor according to an embodiment of the present invention,

FIG. 11 illustrates a schematic view of a seventh manufacturing step of a MEMS capacitive pressure sensor according to an embodiment of the present invention,

FIG. 12 illustrates a schematic view of an eighth manufacturing step of a MEMS capacitive pressure sensor according to an embodiment of the present invention,

FIG. 13 illustrates a schematic view of a ninth manufacturing step of a MEMS capacitive pressure sensor according to an embodiment of the present invention,

FIG. 14 illustrates a schematic view of a tenth manufacturing step of a MEMS capacitive pressure sensor according to an embodiment of the present invention,

FIG. 15 illustrates a schematic view of an eleventh manufacturing step of a MEMS capacitive pressure sensor according to an embodiment of the present invention,

FIG. 16 illustrates a schematic view of a twelfth manufacturing step of a MEMS capacitive pressure sensor according to an embodiment of the present invention,

FIG. 17 illustrates a schematic view of a thirteenth manufacturing step of a MEMS capacitive pressure sensor according to an embodiment of the present invention,

FIG. 18 illustrates a schematic view of a fourteenth manufacturing step of a MEMS capacitive pressure sensor according to an embodiment of the present invention,

FIG. 19 illustrates a schematic view of a first manufacturing step of a MEMS capacitive pressure sensor according to another embodiment of the present invention,

FIG. 20 illustrates a schematic view of a second manufacturing step of a MEMS capacitive pressure sensor according to another embodiment of the present invention,

FIG. 21 illustrates a schematic view of a third manufacturing step of a MEMS capacitive pressure sensor according to another embodiment of the present invention,

FIG. 22 illustrates a schematic view of a fourth manufacturing step of a MEMS capacitive pressure sensor according to another embodiment of the present invention,

FIG. 23 illustrates a schematic view of a fifth manufacturing step of a MEMS capacitive pressure sensor according to another embodiment of the present invention,

FIG. 24 illustrates a schematic view of a sixth manufacturing step of a MEMS capacitive pressure sensor according to another embodiment of the present invention,

FIG. 25 illustrates a schematic view of a seventh manufacturing step of a MEMS capacitive pressure sensor according to another embodiment of the present invention,

FIG. 26 illustrates a schematic view of an eighth manufacturing step of a MEMS capacitive pressure sensor according to another embodiment of the present invention,

FIG. 27 illustrates a schematic view of a ninth manufacturing step of a MEMS capacitive pressure sensor according to another embodiment of the present invention,

FIG. 28 illustrates a schematic view of a tenth manufacturing step of a MEMS capacitive pressure sensor according to another embodiment of the present invention,

FIG. 29 illustrates a schematic view of an eleventh manufacturing step of a MEMS capacitive pressure sensor according to another embodiment of the present invention,

FIG. 30 illustrates a schematic view of a twelfth manufacturing step of a MEMS capacitive pressure sensor according to another embodiment of the present invention,

FIG. 31 illustrates a schematic view of a thirteenth manufacturing step of a MEMS capacitive pressure sensor according to another embodiment of the present invention,

FIG. 32 illustrates a schematic view of a fourteenth manufacturing step of a MEMS capacitive pressure sensor according to another embodiment of the present invention, and

FIG. 33 illustrates a schematic view of a fifteenth manufacturing step of a MEMS capacitive pressure sensor according to another embodiment of the present invention.

### EMBODIMENTS

Certain embodiments of the present invention relate to a MEMS capacitive pressure sensor which is applicable in an increased operational pressure range. The sensor comprises a pedestal protruding from at least one of a first electrode (bottom electrode) and a deformable second electrode (top electrode) into a chamber of the sensor. The pedestal will mechanically connect both electrodes at a specific pressure, thus stiffening the structure of the sensor. Measurement can be continued after mechanically connecting the electrodes via the pedestal. The sensor may be, for example, used in measurement of atmospheric pressure before mechanically connecting the electrodes by means of the pedestal. Measurement of hydrostatic pressure may take place after mechanically connecting the electrodes by means of the pedestal, for instance. The sensor provides an increased operational pressure range. Further, certain embodiments of the present invention relate to a method for manufacturing a MEMS capacitive pressure sensor.

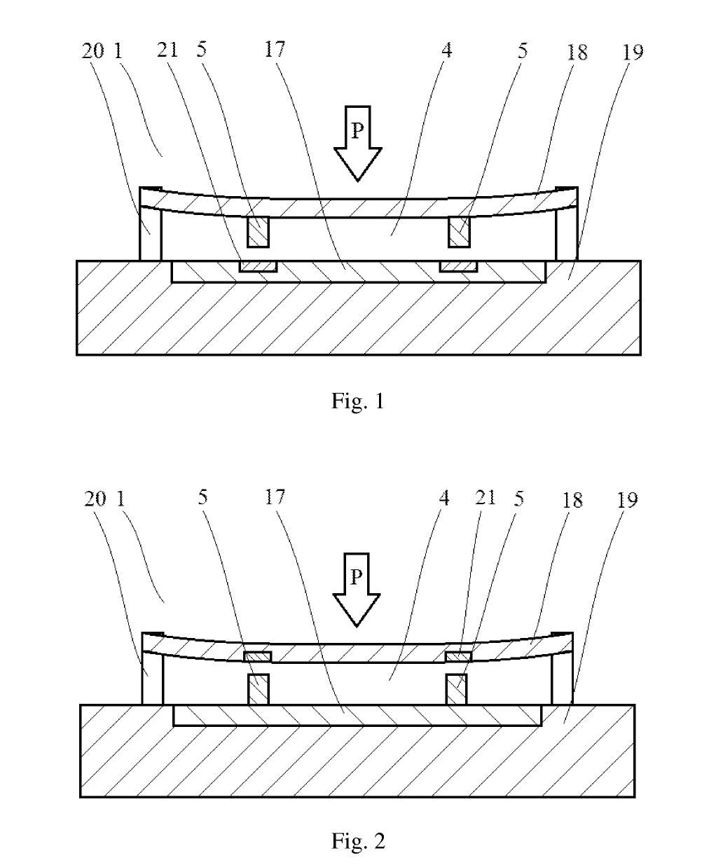

In FIG. 1 a schematic view of a MEMS capacitive pressure sensor 1 is illustrated, wherein a deformable electrode 18 includes a pedestal 5 in accordance with at least some embodiments of the present invention. The sensor 1 also includes a first electrode 17 which is fixedly attached to a substrate 19. The substrate 19 is a standard silicon wafer. The substrate 19 may further include semiconductor devices (not shown). Further, the sensor 1 includes a deformable second electrode 18 which is supported by spacers 20. The spacers 20 are made of insulating material and configured to electrically insulate the first electrode 17 and the second electrode 18. A chamber 4 is formed between the first electrode 17 and the second electrode 18. The chamber 4 electrically insulates the first electrode 17 and the second electrode 18. Additionally, the second electrode 18 includes a pedestal 5 protruding from the second electrode 18 into the chamber 4. The pedestal 5 is formed as a single ring.

The first electrode 17, the second electrode 18, and the chamber 4 form a capacitive structure. When a pressure P is applied on the second electrode 18, the second electrode 18 is deformed. Since the distance between the first electrode 17 and the second electrode 18 changes, the capacitance of the capacitive structure changes. This capacitance is then measured to determine the pressure P applied to the deformable second electrode 18. According to certain embodiments, the first electrode 17 includes an insulating layer 21 on the opposite side of the pedestal 5. The insulating layer 21 is configured to electrically insulate the first electrode 17 and the second electrode 18.

In FIG. 2 a schematic view of a MEMS capacitive pressure sensor 1 is illustrated, wherein a fixed electrode 17 includes a pedestal 5 in accordance with at least some embodiments of the present invention is illustrated. The sensor 1 includes a first electrode 17 which is fixedly attached to a substrate 19. The substrate 19 a standard silicon wafer. Further, the sensor 1 includes a deformable second electrode 18 which is supported by spacers 20. The spacers 20 are made of insulating material and configured to electrically insulate the first electrode 17 and the second electrode 18. A chamber 4 is formed between the first electrode 17 and the second electrode 18. The chamber 4 electrically insulates the first electrode 17 and the second electrode 18. Additionally, the first electrode 17 includes a pedestal 5 protruding from the first electrode 17 into the chamber 4. The pedestal 5 is formed as a single ring.

The first electrode 17, the second electrode 18, and the chamber 4 form a capacitive structure. When a pressure P is applied on the second electrode 18, the second electrode 18 is deformed. Since the distance between the first electrode 17 and the second electrode 18 changes, the capacitance of the capacitive structure changes. This capacitance is then measured to determine the pressure P applied to the deformable second electrode 18. According to certain embodiments, the second electrode 18 includes an insulating layer 21 on the opposite side of the pedestal 5. The insulating layer 21 is configured to electrically insulate the first electrode 17 and the second electrode 18.

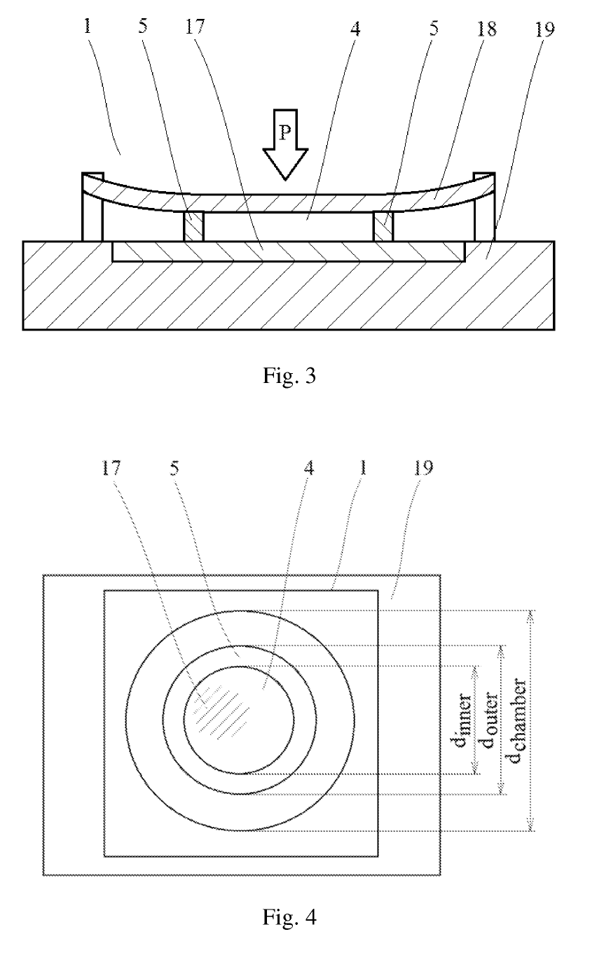

In FIG. 3 a schematic view of a MEMS capacitive pressure sensor 1 in accordance with at least some embodiments of the present invention is illustrated, wherein a pedestal 5 of a first electrode 17 or a second electrode 18 is mechanically in contact with the respective other electrode 17, 18. The sensor 1 is configured to mechanically connect the first electrode 17 and the second electrode 18 at a defined applied pressure by means of the pedestal 5. Mechanical connection of the first electrode 17 and the second electrode 18 will stiffen the deformable second electrode 18 in order to avoid overloading of the sensor 1.

When the deformable second electrode 18 of the sensor 1 is deformed to a certain point at a defined pressure, the first electrode 17 and the second electrode 18 will be mechanically connected via the pedestal 5. Subsequently, the internal part of the deformable second electrode 18 within the pedestal ring 5 and the external part of the deformable second electrode outside the pedestal ring 5 can be considered as different membranes. These membranes are much stiffer in comparison with the full membrane before mechanically connecting the electrodes 17, 18. Thus, the different membranes can be used for measurement of higher pressure. The pedestal 5 is made from insulating material or includes an insulating layer configured to electrically insulate the first electrode 17 and the second electrode 18. According to certain embodiments, at least one of the first electrode 17 and the second electrode 18 includes an insulating layer on the opposite side of the pedestal 5. The insulating layer is configured to electrically insulate the first electrode 17 and the second electrode 18 during mechanical connection.

Pressure measurement can continue after mechanically connecting the first electrode 17 and the second electrode 18. The second electrode 18 can further deflect within and outside of the pedestal ring 5 of the first electrode 17. Changes of the capacitance can be measured after mechanically connecting the electrodes 17, 18, thus increasing the operational pressure range of the sensor 1.

The sensor 1 shown allows measurement of low pressures, e.g. atmospheric pressure, when the full membrane is used. Additionally, the sensor allows measurement of high pressure, e.g. hydrostatic pressure, when the second electrode 18 is mechanically connected to the first electrode 17 and the stiffened parts of the membrane are used at the same time. Parameters of the sensor 1 such as an inner diameter dᵢₙₙₑᵣ of the pedestal 5, an outer diameter dₒᵤₜₑᵣ of the pedestal 5, a diameter d_{chamber} of the chamber 4, a height h_{pedestal} of the pedestal, a height h_{chamber} of the chamber 4, and a thickness t_{membrane} of a deformable membrane affect the measurable pressure range.

In FIG. 4 a schematic cross sectional view of a MEMS capacitive pressure sensor 1 in accordance with at least some embodiments of the present invention is illustrated. A pedestal 5 is formed as a ring having an inner diameter dᵢₙₙₑᵣ, an outer diameter dₒᵤₜₑᵣ, and a height h_{pedestal}. According to certain embodiments, the sensor 1 may comprise two or more pedestals 5. In this case, each pedestal 5 has a different inner diameter dᵢₙₙₑᵣ, outer diameter dₒᵤₜₑᵣ, and height h_{pedestal}. The height h_{pedestal} of each pedestal 5 protruding into the chamber 4 then increases in a direction radially outwards from a central axis of the chamber 4. With increasing pressure the outermost pedestal ring will mechanically connect the first electrode 17 and the second electrode 18 first. Subsequent mechanical connections may be made under increasing pressure by pedestals arranged in a direction radially inwards from the outermost pedestal.

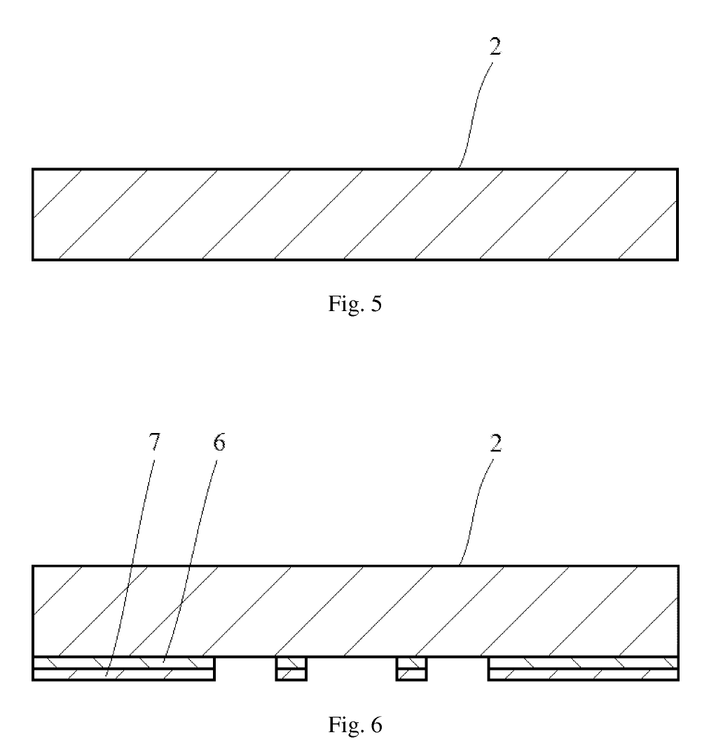

A first manufacturing method of a MEMS capacitive pressure sensor in accordance with at least some embodiments of the present invention is illustrated in FIGS. 5 to 18.

In FIG. 5 a schematic view of a first manufacturing step of a MEMS capacitive pressure sensor according to an embodiment of the present invention is illustrated. A first substrate is used to start the manufacturing. The first substrate is typically a first silicon wafer 2.

In FIG. 6 a schematic view of a second manufacturing step of a MEMS capacitive pressure sensor according to an embodiment of the present invention is illustrated. A masking layer comprising a first oxide layer 6 and a nitride layer 7 is made on a surface of the first silicon wafer 2. The first oxide layer 6 is arranged between the first silicon wafer 2 and the nitride layer 7. The thickness of the first oxide layer 6 may be 500 [nm] and the thickness of the nitride layer 7 may be 300 [nm], for instance. Then patterning of the masking layer takes place. The masking layer is required to prepare the first silicon wafer 2 for a local oxidation process (LOCOS process) at a later stage.

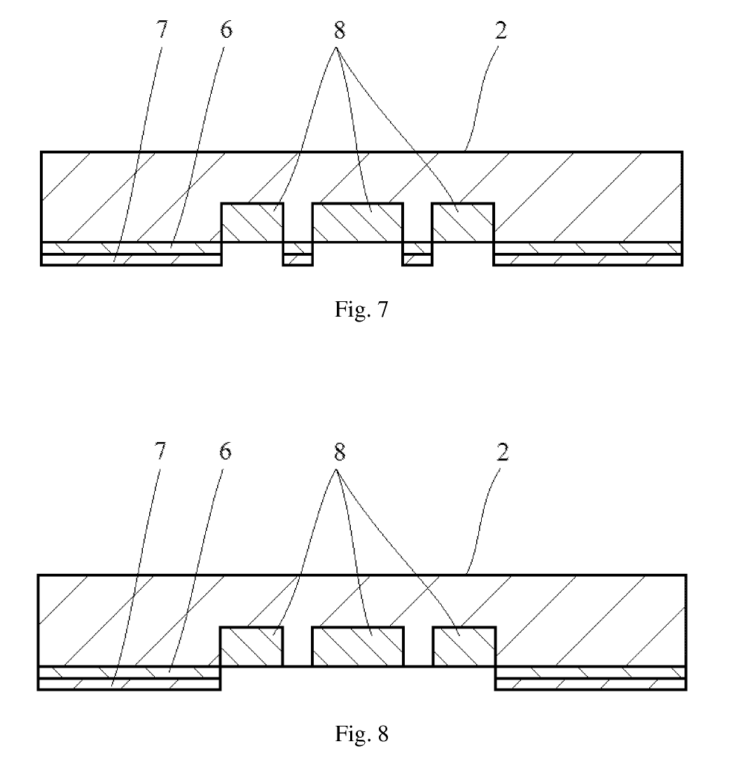

In FIG. 7 a schematic view of a third manufacturing step of a MEMS capacitive pressure sensor according to an embodiment of the present invention is illustrated. Local oxidation (LOCOS) of the first silicon wafer 2 takes place in the areas where the surface of the first silicon wafer 2 is not coated by the masking layer. The local oxidation may be, for example, performed at a temperature of about 1000 [° C.]. A silicon oxide layer 8 is formed in the areas selected by means of the patterned masking layer.

In FIG. 8 a schematic view of a fourth manufacturing step of a MEMS capacitive pressure sensor according to an embodiment of the present invention is illustrated. The masking layer in the centre part is removed. In other words, the oxide layer 6 and the nitride layer 7 are only removed between the areas where a silicon oxide layer 8 has been formed.

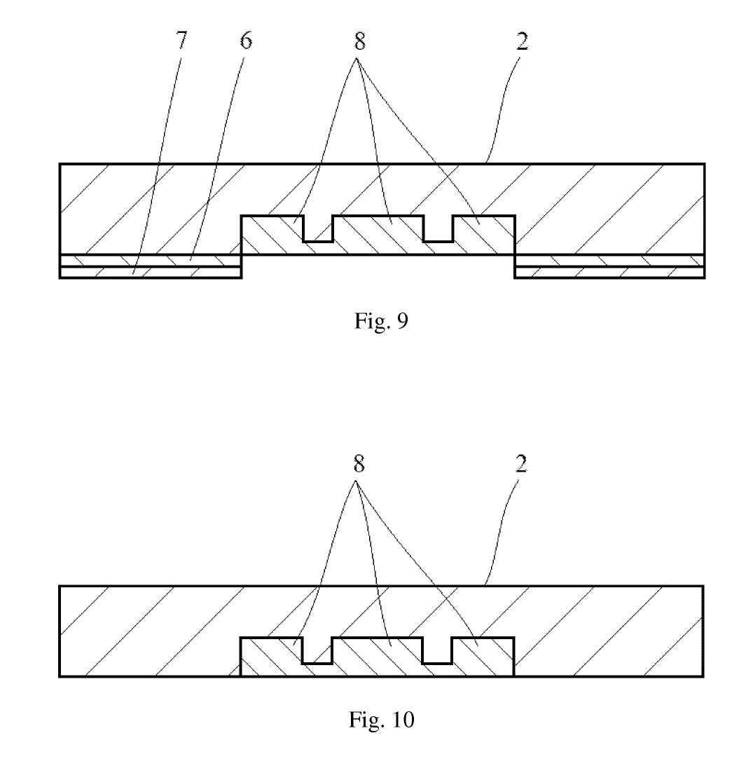

In FIG. 9 a schematic view of a fifth manufacturing step of a MEMS capacitive pressure sensor according to an embodiment of the present invention is illustrated. A second local oxidation is performed in order to form silicon oxide between the previously formed silicon oxide areas. The local oxidation may be, for example, performed at a temperature of about 1000 [° C.]. The thickness of the previously formed silicon oxide layer 8 is greater than the thickness of the subsequently formed silicon oxide.

In FIG. 10 a schematic view of a sixth manufacturing step of a MEMS capacitive pressure sensor according to an embodiment of the present invention is illustrated. The masking layer on the surface of the first silicon wafer 2, i.e. the first oxide layer 6 and the nitride layer 7, is removed.

In FIG. 11 a schematic view of a seventh manufacturing step of a MEMS capacitive pressure sensor according to an embodiment of the present invention is illustrated. The silicon oxide layer 8 is wet etched. By means of removing the silicon oxide a cavity 9 is formed in the first silicon wafer 2. Additionally, a pedestal 5 protruding from the first silicon wafer 2 into the cavity 9 is formed as a ring.

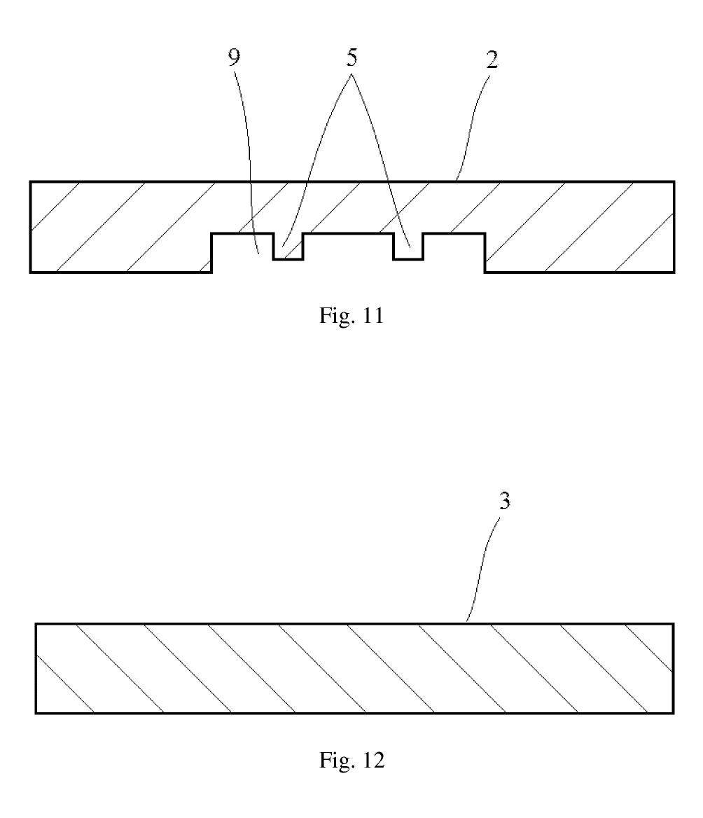

In FIG. 12 a schematic view of an eighth manufacturing step of a MEMS capacitive pressure sensor according to an embodiment of the present invention is illustrated. The manufacturing is continued by providing a second silicon wafer 3.

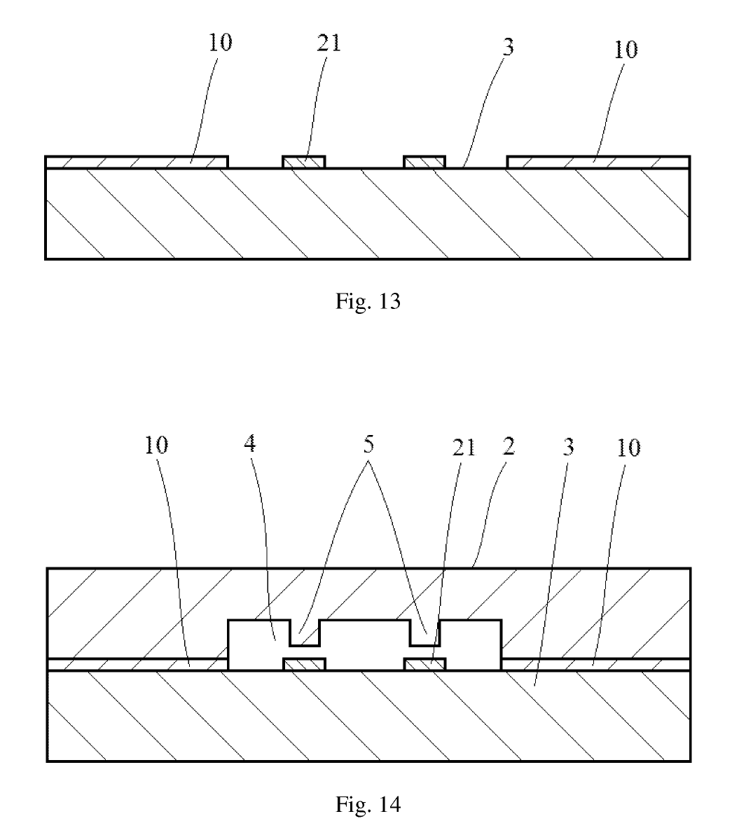

In FIG. 13 a schematic view of a ninth manufacturing step of a MEMS capacitive pressure sensor according to an embodiment of the present invention is illustrated. A second oxide layer 10 is thermally deposited on the surface of the second silicon wafer 3. Subsequently, the second oxide layer 10 is patterned. An insulating layer 21 formed as a ring is provided to the second silicon wafer 3. The insulating layer 21 may also be, for example, an oxide layer.

In FIG. 14 a schematic view of a tenth manufacturing step of a MEMS capacitive pressure sensor according to an embodiment of the present invention is illustrated. Aligned fusion bonding of the first silicon wafer 2 and the second silicon wafer 3 takes place, thus forming a chamber 4 between the wafers 2, 3. Bonding is performed under complete or partial vacuum conditions. Therefore, a vacuum is created in the chamber 4, i.e. the pressure in the chamber 4 is substantially lower than the atmospheric pressure. The pedestal 5 protrudes from the first substrate 2 into the chamber 4.

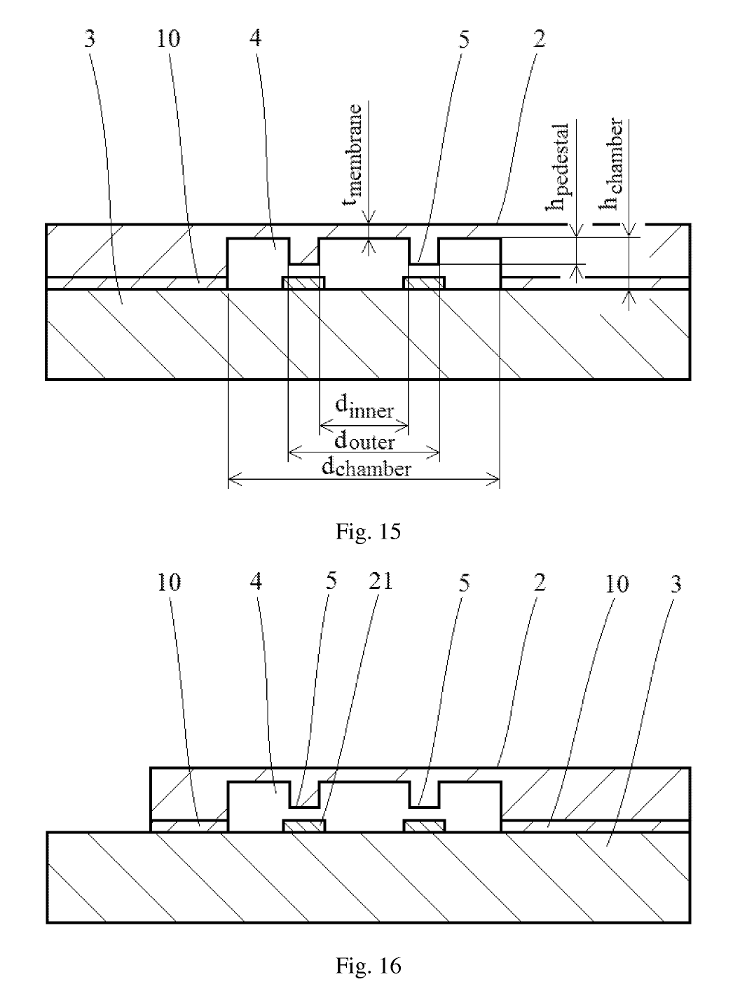

In FIG. 15 a schematic view of a eleventh manufacturing step of a MEMS capacitive pressure sensor according to an embodiment of the present invention is illustrated. Grinding and polishing of the surface of the first silicon wafer 2 facing away from the second silicon wafer 3 is performed. The thickness t_{membrane} of the deformable membrane, i.e. the portion of the first silicon wafer 2 covering the chamber 4, between the chamber 4 and the surface of the first silicon wafer 2 facing away from the second silicon wafer 3 is depending on the expected pressure range. Other parameters affecting the pressure range are e.g. the diameter d_{chamber} of the chamber 4, the inner diameter dᵢₙₙₑᵣ of the pedestal 5, the outer diameter dₒᵤₜₑᵣ of the pedestal 5, the height h_{pedestal} of the pedestal 5, and the height h_{chamber} of the chamber 4.

In FIG. 16 a schematic view of a twelfth manufacturing step of a MEMS capacitive pressure sensor according to an embodiment of the present invention is illustrated. The first silicon wafer 2 is partially deep etched and the second oxide layer 10 is partially removed.

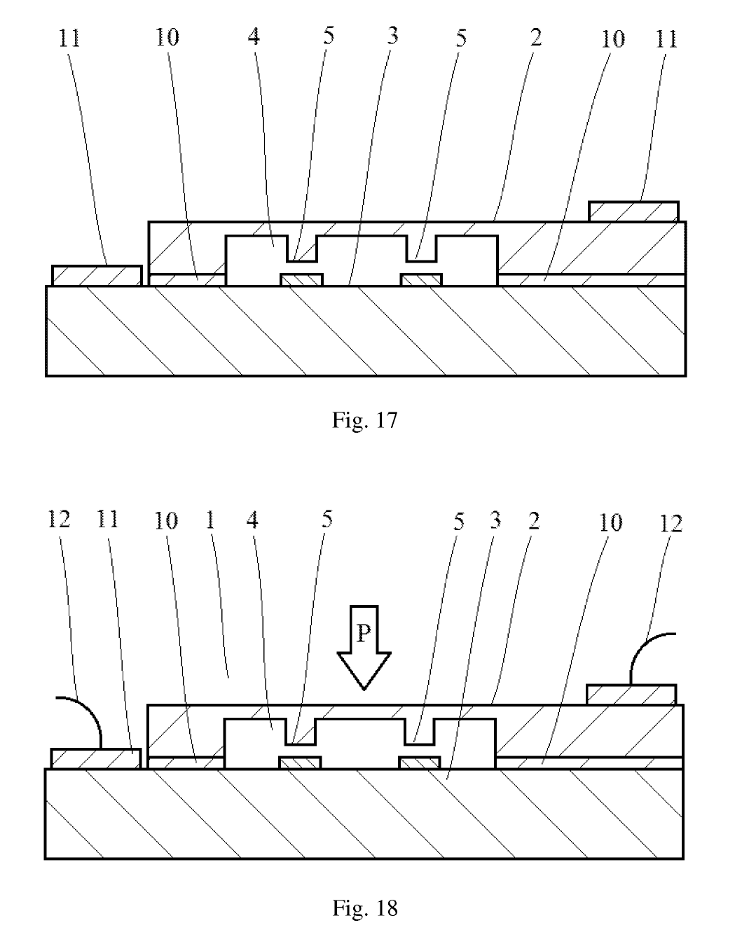

In FIG. 17 a schematic view of a thirteenth manufacturing step of a MEMS capacitive pressure sensor according to an embodiment of the present invention is illustrated. Conductive material layers are deposited on the first silicon wafer 2 and the second silicon wafer 3, thus forming contact structures 11. The contact structures 11 can include one, two or several layers of one, two or several metals. The contact structures 11 may be made of aluminum, for instance. The contact structures 11 are typically applied using a mechanical mask. Of course, any other suitable method can be used. The thickness of the contact structures 11 may be, for example, about 1 [μm]. Other possible metals include, but are not limited to, molybdenum, gold, and copper, for instance.

In FIG. 18 a schematic view of a fourteenth manufacturing step of a MEMS capacitive pressure sensor according to an embodiment of the present invention is illustrated. Wire bonding of the manufactured structure is performed as last manufacturing step of the MEMS capacitive pressure sensor 1. A sensor 1 comprising a pedestal 5 protruding from the second electrode 18 into the chamber 4 is provided as a result. The first silicon wafer 2 including the pedestal 5 represents a deformable electrode 18 comprising a deformable membrane. The second silicon wafer 3 represents a fixed electrode 17.

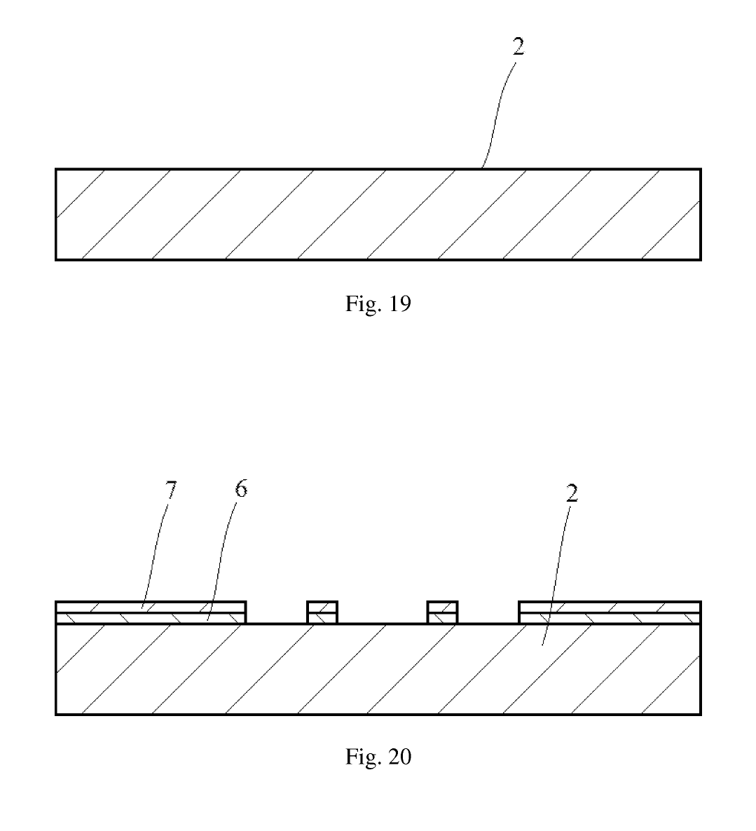

A further manufacturing method of a MEMS capacitive pressure sensor in accordance with at least some embodiments of the present invention is illustrated in FIGS. 19 to 33.

In FIG. 19 a schematic view of a first manufacturing step of a MEMS capacitive pressure sensor according to another embodiment of the present invention is illustrated. A first substrate is used to start the surface micromechanical process. The first substrate is typically a first silicon wafer 2.

In FIG. 20 a schematic view of a second manufacturing step of a MEMS capacitive pressure sensor according to another embodiment of the present invention is illustrated. A patterned masking layer comprising a first oxide layer 6 and a nitride layer 7 is made on a surface of the first silicon wafer 2. The first oxide layer 6 is arranged between the first silicon wafer 2 and the nitride layer 7. The thickness of the first oxide layer 6 may be in the range between 300 [nm] and 700 [nm], for example 500 [nm], and the thickness of the nitride layer 7 may be in the range between 200 [nm] and 400 [nm], for example 300 [nm]. The masking layer is required to prepare the first silicon wafer 2 for a double local oxidation process (LOCOS process) at a later stage.

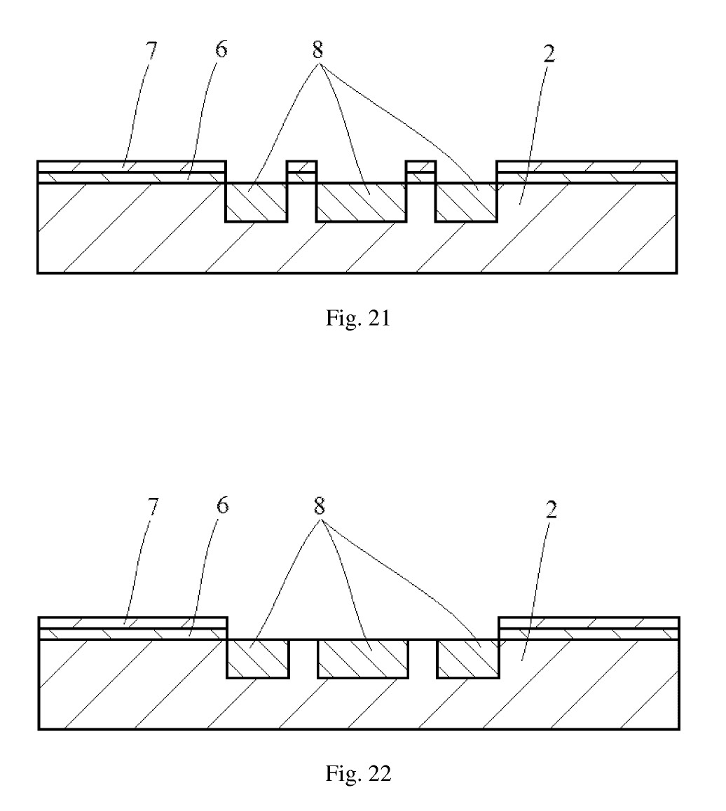

In FIG. 21 a schematic view of a third manufacturing step of a MEMS capacitive pressure sensor according to another embodiment of the present invention is illustrated. Double local oxidation (LOCOS) of the first silicon wafer 2 takes place in the areas where the surface of the first silicon wafer 2 is not coated by the masking layer. The local oxidation may be performed at a temperature in a range between 800 [° C.] and 1200 [° C.], for example at a temperature of 1000 [° C.]. A silicon oxide layer 8 is formed in the areas selected by means of the patterned masking layer.

In FIG. 22 a schematic view of a fourth manufacturing step of a MEMS capacitive pressure sensor according to another embodiment of the present invention is illustrated. The masking layer in the centre part is removed. In other words, the oxide layer 6 and the nitride layer 7 are only removed between the areas where a silicon oxide layer 8 has been formed.

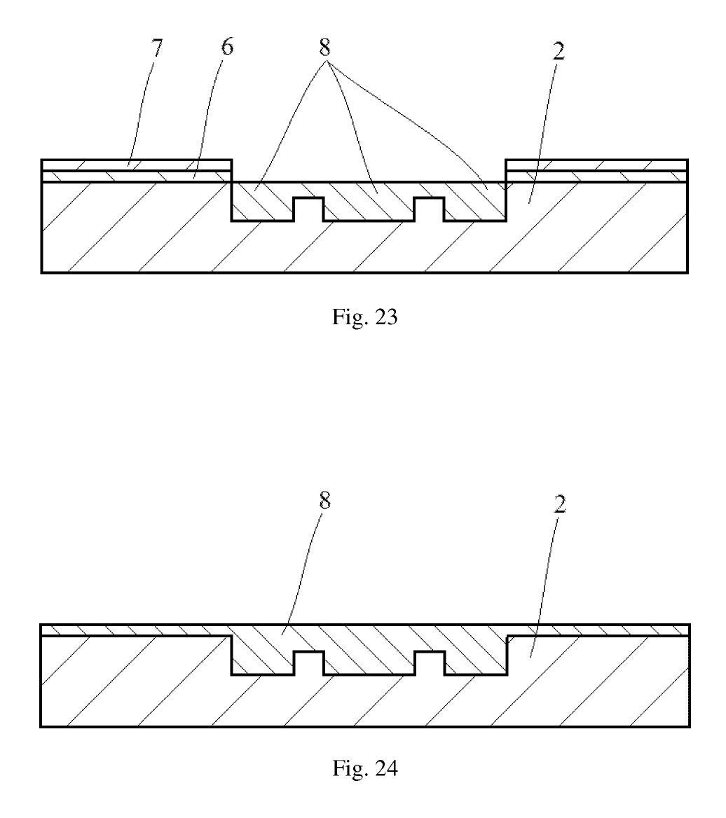

In FIG. 23 a schematic view of a fifth manufacturing step of a MEMS capacitive pressure sensor according to another embodiment of the present invention is illustrated. A second local oxidation is performed in order to form silicon oxide between the previously formed silicon oxide areas. The local oxidation may be performed at a temperature in a range between 800 [° C.] and 1200 [° C.], for example at a temperature of 1000 [° C.]. The thickness of the previously formed silicon oxide layer 8 is greater than the thickness of the subsequently formed silicon oxide.

In FIG. 24 a schematic view of a sixth manufacturing step of a MEMS capacitive pressure sensor according to another embodiment of the present invention is illustrated. The nitride layer 7 is removed. The first oxide layer 6 will remain on the surface of the first silicon wafer 2 and form a united oxide structure with the silicon oxide 8. An insulating layer (not shown) made of electrically insulating material is additionally made on top of the united oxide structure.

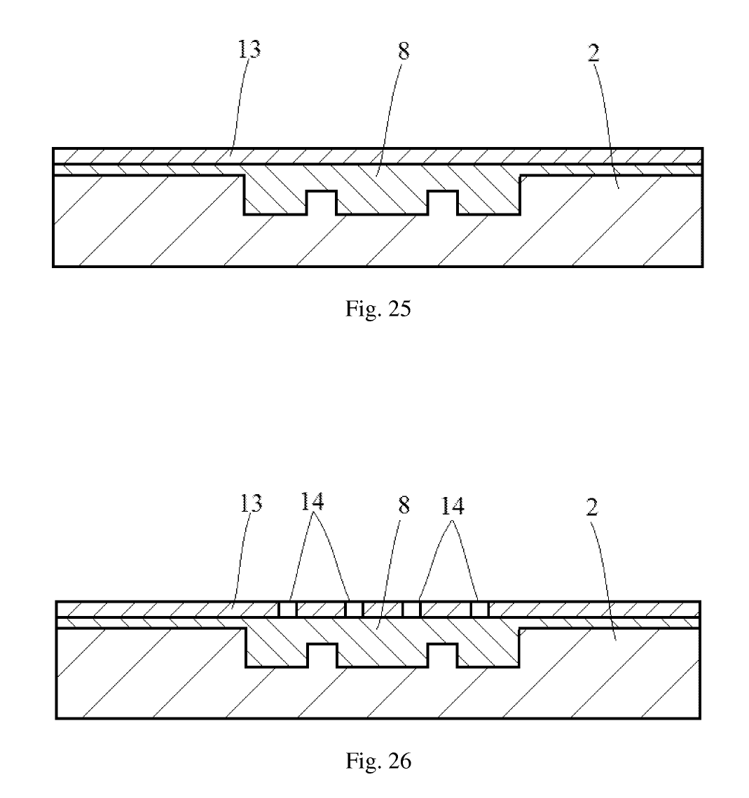

In FIG. 25 a schematic view of a seventh manufacturing step of a MEMS capacitive pressure sensor according to another embodiment of the present invention is illustrated. An LPCVD silicon nitride layer 13 or other insulator is deposited on the silicon oxide 8. The thickness of the LPCVD silicon nitride layer 13 may be in the range between 300 [nm] and 500 [nm], for instance.

In FIG. 26 a schematic view of an eighth manufacturing step of a MEMS capacitive pressure sensor according to another embodiment of the present invention is illustrated. The LPCVD silicon nitride layer 13 is patterned in order to provide holes 14 for sacrificial oxide removal at a later stage. Patterning typically takes place by etching the LPCVD silicon nitride layer 13 locally.

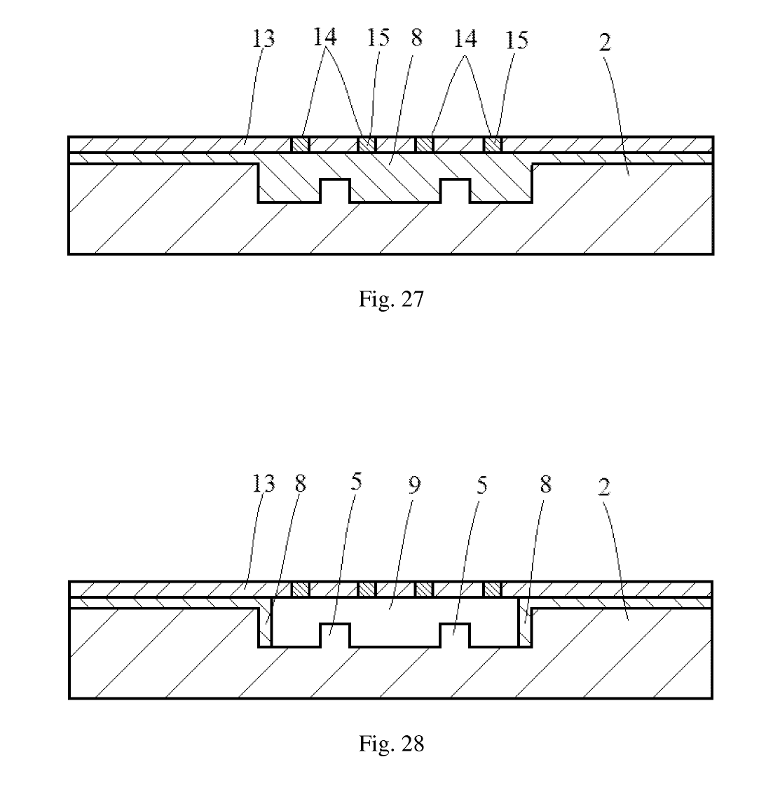

In FIG. 27 a schematic view of a ninth manufacturing step of a MEMS capacitive pressure sensor according to another embodiment of the present invention is illustrated. Porous polysilicon 15 is deposited in the holes 14. The thickness of the porous polysilicon 15 may be in the range between 50 [nm] and 150 [nm], for instance.

In FIG. 28 a schematic view of a tenth manufacturing step of a MEMS capacitive pressure sensor according to another embodiment of the present invention is illustrated. Sacrificial silicon oxide removal is partially performed by HF-vapor etching, thus forming a cavity 9 between the LPCVD silicon nitride layer 13 and the first silicon wafer 2. A pedestal 5 is further formed as a ring. The pedestal 5 protrudes from the first silicon wafer 2 into the cavity 9. The pressure in the cavity 9 equals the atmospheric pressure. An insulating layer (not shown) faces the LPCVD silicon nitride layer 13 in order to electrically insulate the LPCVD silicon nitride layer 13 and the pedestal 5 during mechanical connection.

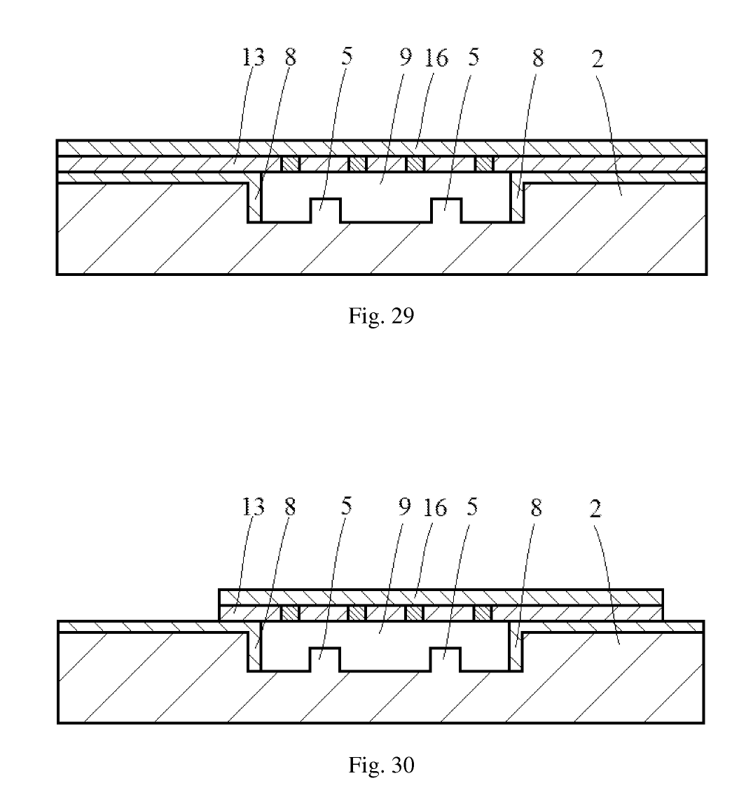

In FIG. 29 a schematic view of an eleventh manufacturing step of a MEMS capacitive pressure sensor according to another embodiment of the present invention is illustrated. An amorphous polysilicon layer 16 is deposited on the LPCVD silicon nitride layer 13. The thickness of the polysilicon layer 16 may be in the range between 300 [nm] and 500 [nm], for instance. Deposition is performed in a partial vacuum or complete vacuum in order to provide a sealed evacuated chamber 4 between the first silicon wafer 2, the LPCVD silicon nitride layer 13, and the polysilicon layer 16. The pressure in the chamber 4 is substantially lower than the atmospheric pressure.

In FIG. 30 a schematic view of a twelfth manufacturing step of a MEMS capacitive pressure sensor according to another embodiment of the present invention is illustrated. The LPCVD silicon nitride layer 13 and the polysilicon layer 16 are patterned.

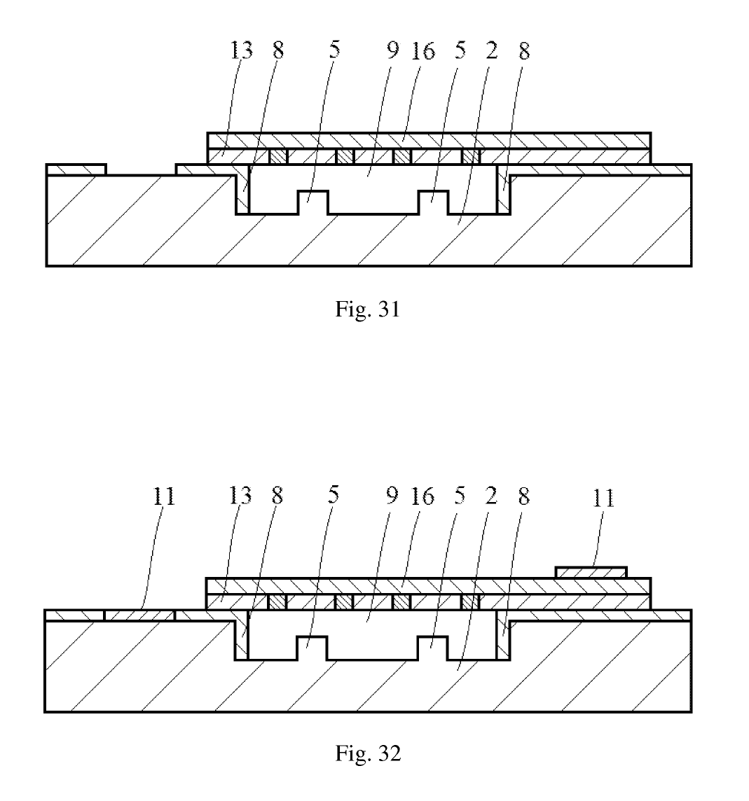

In FIG. 31 a schematic view of a thirteenth manufacturing step of a MEMS capacitive pressure sensor according to another embodiment of the present invention is illustrated. The oxide arranged on the surface of the silicon wafer 2 is patterned.

In FIG. 32 a schematic view of a fourteenth manufacturing step of a MEMS capacitive pressure sensor according to another embodiment of the present invention is illustrated. Conductive material is deposited in the pattern of the oxide arranged on the surface of the silicon wafer 2 and on the polysilicon layer 16, thus forming contact structures 11. The contact structures 11 can include one, two or several layers of one, two or several metals. The contact structures 11 may be made of aluminium, for instance. The thickness of the contact structures 11 may be, for example, about 1 [μm]. Other possible metals include, but are not limited to, molybdenum, gold, and copper, for instance.

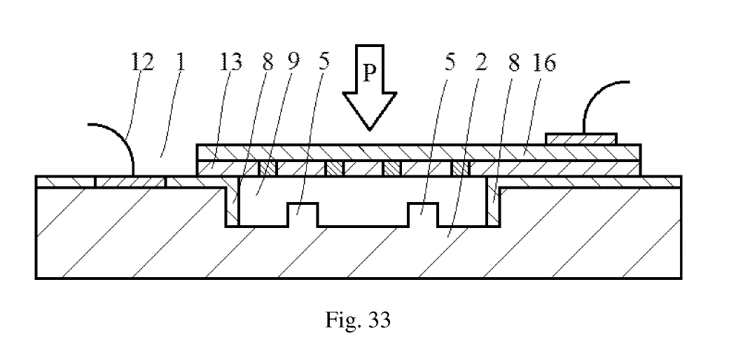

In FIG. 33 a schematic view of a fifteenth manufacturing step of a MEMS capacitive pressure sensor according to another embodiment of the present invention is illustrated. Wire bonding of the manufactured structure is performed as last manufacturing step of the MEMS capacitive pressure sensor 1. A sensor 1 comprising a pedestal 5 protruding from the first electrode 18 into the chamber 4 is provided as a result. The first silicon wafer 2 including the pedestal 5 represents a fixed electrode 17. The LPCVD silicon nitride layer 13 and the polysilicon layer 16 represent a deformable electrode 18 comprising a deformable membrane. An insulating layer (not shown) faces the LPCVD silicon nitride layer 13 in order to electrically insulate the LPCVD silicon nitride layer 13 and the pedestal 5 during mechanical connection.

It is to be understood that the embodiments of the invention disclosed are not limited to the particular structures, process steps, or materials disclosed herein, but are extended to equivalents thereof as would be recognized by those ordinarily skilled in the relevant arts. It should also be understood that terminology employed herein is used for the purpose of describing particular embodiments only and is not intended to be limiting.

Reference throughout this specification to one embodiment or an embodiment means that a particular feature, structure, or characteristic described in connection with the embodiment is included in at least one embodiment of the present invention. Thus, appearances of the phrases “in one embodiment” or “in an embodiment” in various places throughout this specification are not necessarily all referring to the same embodiment. Where reference is made to a numerical value using a term such as, for example, about or substantially, the exact numerical value is also disclosed.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary. In addition, various embodiments and example of the present invention may be referred to herein along with alternatives for the various components thereof. It is understood that such embodiments, examples, and alternatives are not to be construed as de facto equivalents of one another, but are to be considered as separate and autonomous representations of the present invention.

Furthermore, the described features, structures, or characteristics may be combined in any suitable manner in one or more embodiments. In the following description, numerous specific details are provided, such as examples of lengths, widths, shapes, etc., to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

While the forgoing examples are illustrative of the principles of the present invention in one or more particular applications, it will be apparent to those of ordinary skill in the art that numerous modifications in form, usage and details of implementation can be made without the exercise of inventive faculty, and without departing from the principles and concepts of the invention. Accordingly, it is not intended that the invention be limited, except as by the claims set forth below.

The verbs “to comprise” and “to include” are used in this document as open limitations that neither exclude nor require the existence of also un-recited features. The features recited in depending claims are mutually freely combinable unless otherwise explicitly stated. Furthermore, it is to be understood that the use of “a” or “an”, that is, a singular form, throughout this document does not exclude a plurality.

### INDUSTRIAL APPLICABILITY

At least some embodiments of the present invention find industrial application in production of wrist watches. Two different pressure sensors for measuring atmospheric pressure and hydrostatic pressure can be replaced by a single pressure sensor, for instance.

### Acronyms List

MEMS micro-electro-mechanical system
LOCOS local oxidization of silicon
LPCVD low pressure chemical vapor deposition

### REFERENCE SIGNS LIST

1 MEMS capacitive pressure sensor
2 first silicon wafer
3 second silicon wafer
4 chamber
5 pedestal
6 first oxide layer
7 nitride layer
8 silicon oxide layer
9 cavity
10 second oxide layer
11 contact structure
12 wire
13 LPCVD silicon nitride layer
14 hole
15 porous polysilicon
16 polysilicon layer
17 first electrode (bottom electrode)
18 second electrode (top electrode)
19 substrate
20 spacer
21 insulating layer
d_{chamber} diameter of chamber
dᵢₙₙₑᵣ inner diameter of pedestal
dₒᵤₜₑᵣ outer diameter of pedestal
P pressure
t_{membrane} thickness of deformable membrane

### CITATION LIST

### Patent Literature

US 2015/0008543 A1

1. A MEMS capacitive pressure sensor, comprising:
a first electrode,
a deformable second electrode being electrically insulated from the first electrode by means of a chamber between the first electrode and the second electrode, and
wherein at least one of the first electrode and the second electrode includes at least one pedestal protruding into the chamber.

2. The MEMS capacitive pressure sensor according to claim 1, wherein the sensor is configured to mechanically connect the first electrode and the second electrode at a defined applied pressure by means of the pedestal.

3. The MEMS capacitive pressure sensor according to claim 1, wherein the pedestal is made of insulating material or includes an insulating layer which is configured to electrically insulate the first electrode; and the second electrode.

4. The MEMS capacitive pressure sensor according to claim 1, wherein at least one of the first electrode and the second electrode includes an insulating layer configured to electrically insulate the first electrode and the second electrode.

5. (canceled)

6. The MEMS capacitive pressure sensor according to claim 5, wherein at least one of an inner diameter of the pedestal, an outer diameter of the pedestal, a diameter of the chamber, a height of the pedestal, a height of the chamber, and a thickness of a deformable membrane is depending on a predetermined measurable pressure range.

7. The MEMS capacitive pressure sensor according to claim 1, wherein the sensor includes two or more pedestals each having a different height.

8. The MEMS capacitive pressure sensor according to claim 7, wherein the height of the pedestals protruding into the chamber increases in a direction radially outwards.

9. The MEMS capacitive pressure sensor according to claim 1, wherein the pressure in the chamber is substantially lower than the atmospheric pressure.

10. The MEMS capacitive pressure sensor according to claim 1, wherein the second electrode comprises at least one amorphous polysilicon layer.

11. The MEMS capacitive pressure sensor according to claim 1, wherein the first electrode is fixedly attached to a substrate made of insulating material.

12. The MEMS capacitive pressure sensor according to claim 11, wherein the first electrode and the second electrode are electrically connected to a semiconductor device in the substrate.

13. The MEMS capacitive pressure sensor according to claim 1, wherein at least one of the first electrode and the second electrode comprises a silicon wafer.

14. A method for manufacturing a MEMS capacitive pressure sensor, the method comprising:
forming a first electrode;
forming a deformable second electrode, which is electrically insulated from the first electrode by means of a chamber between the first electrode and the second electrode, and
forming at least one pedestal protruding into the chamber from at least one of the first electrode and the second electrode.

15. The method according to claim 14, wherein the deformable second electrode is formed by means of:—arranging a patterned masking layer on a surface of a first silicon wafer,
performing a first local oxidization in a first selected area of the silicon wafer,
partially removing the masking layer,
performing a second local oxidization in a second selected area of the silicon wafer,
removing the masking layer completely, and
etching of silicon oxide.

16. The method according to claim 15, the method further comprising:
grinding a surface of the silicon wafer on an opposite side of the pedestal,
polishing the surface of the silicon wafer on the opposite side of the pedestal.

17. The method according to claim 14 or 15, the method further comprising:
arranging a patterned oxide layer on a surface of a second silicon wafer in order to provide a first electrode,
aligning and bonding the first electrode and the deformable second electrode.

18. The method according to claim 17, wherein bonding the first electrode and the deformable second electrode is performed in a partial vacuum or a complete vacuum.

19. The method according to claim 14, the method comprising the steps of:
providing a patterned masking layer on a surface of a silicon wafer,
performing a first local oxidization in a first selected area of the silicon wafer,
partially removing the masking layer,
performing a second local oxidization in a second selected area of the silicon wafer,
removing a nitride layer of the masking layer,
providing a LPCVD silicon nitride layer or insulating layer,
providing at least one hole in the LPCVD silicon nitride layer or insulating layer,
depositing porous polysilicon in the hole,
at least partially removing silicon oxide from the chamber, and
providing a polysilicon layer on the LPCVD silicon nitride layer or insulating layer.

20. The method according to claim 19, wherein deposition of the polysilicon layer is performed in a partial vacuum or a complete vacuum.

21. The method according to claim 14, the method further comprising:—making of a contact structure which is electrically connected to the first electrode, and
making of a contact structure which is electrically connected to the deformable second electrode.
